(19) United States
(12) Patent Application Publication
(10) Pub. No.: US 2025/0287606 A1
(43) Pub. Date: Sep. 11, 2025

(54) NEURON CIRCUITS FOR A SPIKING NEURAL NETWORK BASED ON A VOLTAGE-CONTROLLED MAGNETIC-TUNNEL-JUNCTION LAYER STACK

(71) Applicant: GlobalFoundries Singapore Pte. Ltd., Singapore (SG)

(72) Inventors: Joel Tan, Singapore (SG); Vinayak Bharat Naik, Singapore (SG); Jia Hao Lim, Singapore (SG)

(21) Appl. No.: 18/596,068

(22) Filed: Mar. 5, 2024

(51) Int. Cl. H10B 61/00; G06N 3/049; H10N 50/01; H10N 50/20; H10N 50/80

(52) U.S. Cl. CPC H10B 61/00; G06N 3/049; H10N 50/01; H10N 50/20; H10N 50/80

(57) ABSTRACT

Structures for a spiking neural network including a magnetic-tunnel-junction layer stack and methods of forming such structures. The structure comprises a leaky-integrate-fire neuron including a magnetic-tunneling-junction layer stack, and a power source connected to the magnetic-tunneling-junction layer stack. The power source is configured to provide a plurality of voltage pulses to the magnetic-tunneling-junction layer stack.

### BACKGROUND

The present disclosure relates to integrated circuits and semiconductor device fabrication and, more specifically, to structures for a spiking neural network including a magnetic-tunnel-junction layer stack and methods of forming such structures.

A neural network is a system of hardware and/or software patterned after the operation of neurons in the human brain. A spiking neural network is a type of neural network that operates using voltage spikes, which are discrete events that take place at points in time, rather than continuous values. Essentially, a voltage spike by any particular neuron occurs upon reaching a sufficiently high potential, after which the potential of the neuron is reset.

Improved structures for a spiking neural network including a magnetic-tunnel-junction layer stack and methods of forming such structures are needed.

### SUMMARY

According to an embodiment of the invention, a structure for a spiking neural network is provided. The structure comprises a leaky-integrate-fire neuron including a magnetic-tunneling-junction layer stack, and a power source connected to the magnetic-tunneling-junction layer stack. The power source is configured to provide a plurality of voltage pulses to the magnetic-tunneling-junction layer stack.

According to an embodiment of the invention, a method of forming a structure for a spiking neural network is provided. The method comprises forming a leaky-integrate-fire neuron including a magnetic-tunneling-junction layer stack. The magnetic-tunneling-junction layer stack is connected to a power source. The power source is configured to provide a plurality of voltage pulses to the magnetic-tunneling-junction layer stack.

### BRIEF DESCRIPTION OF THE DRAWINGS

The accompanying drawings, which are incorporated in and constitute a part of this specification, illustrate various embodiments of the invention and, together with a general description of the invention given above and the detailed description of the embodiments given below, serve to explain the embodiments of the invention. In the drawings, like reference numerals refer to like features in the various views.

FIG. 1 is a cross-sectional view of a magnetic-tunnel-junction layer stack in accordance with embodiments of the invention.

FIG. 2 is a diagrammatic view of a structure including magnetic-tunnel-junction layer stacks in accordance with alternative embodiments of the invention.

### DETAILED DESCRIPTION

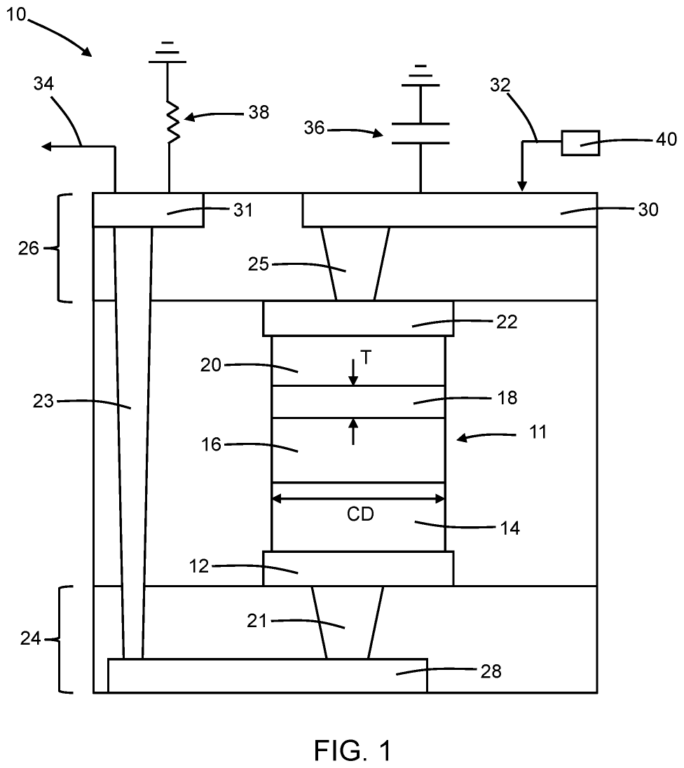

With reference to FIG. 1 and in accordance with embodiments of the invention, a structure 10 for use as a threshold-switching device in a neuron circuit of a spiking neural network may include a magnetic-tunneling-junction layer stack 11. The magnetic-tunneling-junction layer stack 11 may include an electrode 12, a synthetic antiferromagnetic pinning layer 14, a reference layer 16, a tunnel barrier layer 18, a free layer 20, and an electrode 22. The layers 14, 16, 18 of the magnetic-tunneling-junction layer stack 11 are disposed between the electrode 12 and the electrode 22. The layers 14, 16, 18, 20 of the magnetic-tunneling-junction layer stack 11 may be sequentially formed with a stacked arrangement by one or more deposition processes, such as physical vapor deposition processes, and patterned by one or more lithography and etching processes. In alternative embodiments, the magnetic-tunneling-junction layer stack 11 may include additional layers arranged between the electrode 12 and electrode 22.

The electrode 12 may be comprised of a non-magnetic conductor, such as tantalum or tantalum nitride. The synthetic antiferromagnetic pinning layer 14 may be disposed on the electrode 12. The synthetic antiferromagnetic pinning layer 14 may be comprised of a magnetic material, such as multiple bilayers of cobalt and palladium or multiple bilayers of cobalt and platinum. The reference layer 16 may be disposed on the synthetic antiferromagnetic pinning layer 14. The reference layer 16 may be comprised of a ferromagnetic material, such as a cobalt-iron-boron alloy. The tunnel barrier layer 18 may be disposed on the reference layer 16. The tunnel barrier layer 18 may be comprised of a non-magnetic and electrically-insulating dielectric material, such as magnesium oxide. The free layer 20 may be disposed on the tunnel barrier layer 18. The free layer 20 may be comprised of a ferromagnetic material, such as a cobalt-iron-boron alloy. The electrode 22, which may be positioned on the free layer 20, may be comprised of a non-magnetic conductor, such as tantalum or tantalum nitride.

In an embodiment, the tunnel barrier layer 18 may have a thickness T in a range of 1 nanometer to 100 nanometers. In an embodiment, the tunnel barrier layer 18 may have a thickness T in a range of 10 nanometers to 100 nanometers, which may endow the magnetic-tunneling-junction layer stack 11 with a low leakage current, reduced power consumption, and a high endurance during operation.

The magnetization of the reference layer 16 is pinned such that the magnetization is fixed and cannot switch under the influence of a bias voltage applied across the magnetic-tunneling-junction layer stack 11. The synthetic antiferromagnetic pinning layer 14 may provide a static magnetic field with a magnetization that functions to assist with the pinning of the magnetization of the reference layer 16. The magnetization of the free layer 20 can be switched or flipped to be parallel to the magnetization of the reference layer 16 or antiparallel to the magnetization of the reference layer 16. The magnetic-tunneling-junction layer stack 11 is characterized by a low-resistance state across when the magnetization of the free layer 20 is parallel to the magnetization of the reference layer 16. The magnetic-tunneling-junction layer stack 11 is characterized by a high-resistance state when the magnetization of the free layer 20 is antiparallel to the magnetization of the reference layer 16. The electrical resistance in the antiparallel condition is greater than the electrical resistance in the parallel condition. The different conditions for the magnetization of the free layer 20 are separated by an energy barrier for switching that must be overcome to permit switching.

The magnetic-tunneling-junction layer stack 11 may be located between a wiring level 24 and a wiring level 26 of an interconnect structure that is fabricated by back-end-of-line processes. The wiring levels 24, 26 of the interconnect structure may be formed by deposition, polishing, lithography, and etching techniques characteristic of a damascene process. Specifically, for each of the wiring levels 24, 26, one or more dielectric layers may be deposited and patterned using lithography and etching processes to define trenches and via openings that are lined with a barrier layer and filled by a planarized metal to define interconnects 28, 30, 31 and vias 21, 23, 25. Each dielectric layer may be comprised of a dielectric material, such as silicon dioxide or a low-k dielectric material, and the interconnects 28, 30, 31 and vias 21, 23, 25 may be comprised of a metal, such as copper or aluminum.

The interconnect 28 in the wiring level 24 may be physically and electrically connected by the via 21 to the electrode 12 and by the via 23 to the interconnect 31 in the wiring level 26. The interconnect 30 in the wiring level 26 may be physically and electrically connected by the via 25 to the electrode 22.

The structure 10 may include an input 32, an output 34, a capacitor 36, and a resistor 38 arranged in a neuron circuit, and a power source 40 may be coupled to the input 32. The input 32 is coupled by the via 25 and the interconnect 30 to the electrode 22 of the magnetic-tunneling-junction layer stack 11. The output 34 is coupled by the vias 21, 23 and the interconnects 28, 31 to the electrode 12 of the magnetic-tunneling-junction layer stack 11. The capacitor 36 is also coupled to the interconnect 30, and the resistor 38 is coupled to the interconnect 30.

In particular, the power source 40 may be connected by the interconnect 31 and via 25 to the electrode 22 that is adjacent to the free layer 20. The power source 40 is configured to provide voltages pulses to the magnetic-tunneling-junction layer stack 11 that have a magnitude sufficient to cause a state change by causing the free layer 20 to switch directions. In an embodiment, the power source 40 may be a power supply integrated into driving circuitry for the structure 10. In an alternative embodiment, the power source 40 may be an upstream threshold-switching device in the structure 10. The capacitor 36 is disposed on the input side of the magnetic-tunneling-junction layer stack 11 and coupled in parallel with the magnetic-tunneling-junction layer stack 11, and the resistor 38 is disposed on the output side of the magnetic-tunneling-junction layer stack 11. The capacitor 36 and resistor 38 are both coupled to ground.

The magnetic-tunneling-junction layer stack 11 is characterized by an energy barrier for switching between the parallel and antiparallel conditions that can be lowered using the voltage-controlled magnetic anisotropy (VCMA) effect. Specifically, the material of the free layer 20 has a magnetic anisotropy (i.e., a preferred magnetic axis) that can be modulated to lower the energy barrier and cause switching between the low-resistance state and the high-resistance state. The voltage pulses received from the power source 40 are integrated by the capacitor 36 and, as the integrated voltage from accumulated voltage pulses rises above a characteristic threshold voltage of the magnetic-tunneling-junction layer stack 11, the free layer 20 of the magnetic-tunneling-junction layer stack 11 is susceptible to switching and then resetting when the voltage falls below a characteristic holding voltage of the magnetic-tunneling-junction layer stack 11.

In use, voltage pulses generated by the power source 40 may be supplied as a pulse train to the input 32 of the magnetic-tunneling-junction layer stack 11. The integration of the train of voltage pulses charges the capacitor 36, and the magnetic-tunneling-junction layer stack 11 fires upon the capacitor 36 reaching a voltage greater than the characteristic threshold voltage of the magnetic-tunneling-junction layer stack 11. The discharge of the capacitor 36 produces state-switching of the free layer 20 by the voltage-controlled magnetic anisotropy effect. As the capacitor 36 discharges, the voltage eventually drops below the characteristic holding voltage of the magnetic-tunneling-junction layer stack 11 and the free layer 20 resets back to its initial resistance state. A voltage spike is produced at the output 34 by the leaky-integrate-fire functionality. The charging and discharging process can be repeated to generate multiple voltage spikes at the output 34.

The state-switching exhibited by the magnetic-tunneling-junction layer stack 11 enables the formation of a structure 10 suitable for deployment as a threshold-switching device in a neuron circuit for a spiking neural network. In particular, the magnetic-tunneling-junction layer stack 11 may provide a leaky-integrate-fire neuron that relies on volatile threshold-switching to generate a spike and that exhibits a high spike frequency and a high endurance cycle, as well as a device performance that does not degrade over time in comparison with resistive-random-access memory devices deployed in a spiking neural network. The leaky-integrate-fire neuron based on the magnetic-tunneling-junction layer stack 11 may also exhibit a faster recovery speed and a lower variability in cycle-to-cycle resistance and device-to-device resistance than other types of neurons. In that regard, the magnetic-tunneling-junction layer stack 11 benefits from inherently fast magnetic switching to provide short set and reset times, as well as high spike rates. The leaky-integrate-fire neuron based on the magnetic-tunneling-junction layer stack 11 may enable a spiking neural network for deployment in large computation applications.

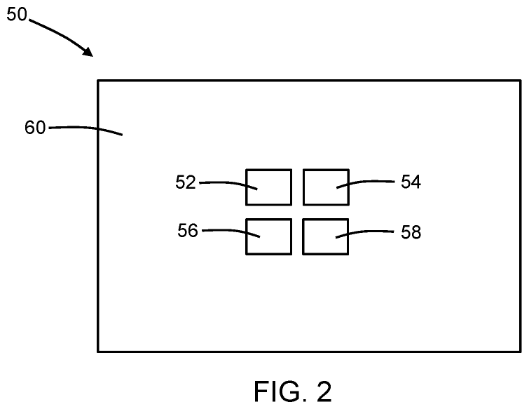

With reference to FIG. 2 and in accordance with embodiments of the invention, a structure 50 may include domains 52, 54, 56, 58 that are integrated as distinct leaky-integrate-fire neurons on the same chip 60. Each of the domains 52, 54, 56, 58 may include an instance of the structure 10 in which the magnetic-tunneling-junction layer stack 11 is characterized by a different spiking frequency and threshold voltage. In an embodiment, the thickness T of the tunnel barrier layer 18 can differ between the different domains 52, 54, 56, 58 to provide different spiking frequencies and threshold voltages on the same chip 60. In an embodiment, the critical dimension CD of the magnetic-tunneling-junction layer stack 11 can differ between the different domains 52, 54, 56, 58 to provide different spiking frequencies and threshold voltages on the same chip 60. For example, the critical dimension CD may be assessed as the smallest dimension (e.g., smallest width) in a plane transverse to the thickness T of the tunnel barrier layer 18. In an embodiment, the thickness T of the tunnel barrier layer 18 and the critical dimension CD of the magnetic-tunneling-junction layer stack 11 can differ between the different domains 52, 54, 56, 58 to provide different spiking frequencies and threshold voltages on the same chip 60. As a result, a range of spike frequencies, threshold voltages, and/or integration times can be achieved that is wider than the range achievable with a single leaky-integrate-fire neuron.

The methods as described above are used in the fabrication of integrated circuit chips. The resulting integrated circuit chips can be distributed by the fabricator in raw wafer form (e.g., as a single wafer that has multiple unpackaged chips), as a bare die, or in a packaged form. The chip may be integrated with other chips, discrete circuit elements, and/or other signal processing devices as part of either an intermediate product or an end product. The end product can be any product that includes integrated circuit chips, such as computer products having a central processor or smartphones.

References herein to terms modified by language of approximation, such as “about”, “approximately”, and “substantially”, are not to be limited to the precise value specified. The language of approximation may correspond to the precision of an instrument used to measure the value and, unless otherwise dependent on the precision of the instrument, may indicate a range of +/−10% of the stated value(s).

References herein to terms such as “vertical”, “horizontal”, etc. are made by way of example, and not by way of limitation, to establish a frame of reference. The term “horizontal” as used herein is defined as a plane parallel to a conventional plane of a semiconductor substrate, regardless of its actual three-dimensional spatial orientation. The terms “vertical” and “normal” refer to a direction in the frame of reference perpendicular to the horizontal, as just defined. The term “lateral” refers to a direction in the frame of reference within the horizontal plane.

A feature “connected” or “coupled” to or with another feature may be directly connected or coupled to or with the other feature or, instead, one or more intervening features may be present. A feature may be “directly connected” or “directly coupled” to or with another feature if intervening features are absent. A feature may be “indirectly connected” or “indirectly coupled” to or with another feature if at least one intervening feature is present. A feature “on” or “contacting” another feature may be directly on or in direct contact with the other feature or, instead, one or more intervening features may be present. A feature may be “directly on” or in “direct contact” with another feature if intervening features are absent. A feature may be “indirectly on” or in “indirect contact” with another feature if at least one intervening feature is present. Different features may “overlap” if a feature extends over, and covers a part of, another feature with either direct contact or indirect contact.

The descriptions of the various embodiments of the present invention have been presented for purposes of illustration but are not intended to be exhaustive or limited to the embodiments disclosed. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, or to enable others of ordinary skill in the art to understand the embodiments disclosed herein.

What is claimed is:

1. A structure for a spiking neural network, the structure comprising:
a first leaky-integrate-fire neuron including a first magnetic-tunneling-junction layer stack; and
a power source connected to the first magnetic-tunneling-junction layer stack, the power source configured to provide a plurality of voltage pulses to the first magnetic-tunneling-junction layer stack.

2. The structure of claim 1 wherein the first leaky-integrate-fire neuron includes an input coupled to the power source and an output, and the first magnetic-tunneling-junction layer stack includes a first electrode coupled to the input and a second electrode coupled to the output.

3. The structure of claim 2 wherein the first magnetic-tunneling-junction layer stack includes a free layer adjacent to the first electrode, a reference layer adjacent to the second electrode, and a tunnel barrier layer between the reference layer and the free layer.

4. The structure of claim 3 wherein the first magnetic-tunneling-junction layer stack includes a synthetic antiferromagnetic pinning layer between the reference layer and the second electrode.

5. The structure of claim 3 wherein the tunnel barrier layer has a thickness in a range of 1 nanometer to 100 nanometers.

6. The structure of claim 5 wherein the first magnetic-tunneling-junction layer stack includes a synthetic antiferromagnetic pinning layer between the reference layer and the second electrode.

7. The structure of claim 2 further comprising:
a capacitor coupled to the input; and
a resistor coupled to the output.

8. The structure of claim 7 wherein the capacitor is coupled to the input in parallel with the first magnetic-tunneling-junction layer stack.

9. The structure of claim 7 wherein the resistor is coupled to the output in parallel with the first magnetic-tunneling-junction layer stack.

10. The structure of claim 1 wherein the first magnetic-tunneling-junction layer stack has a first threshold voltage for generating a first voltage spike.

11. The structure of claim 10 further comprising:
a chip; and
a second leaky-integrate-fire neuron including a second magnetic-tunneling-junction layer stack,
wherein the first leaky-integrate-fire neuron and the second leaky-integrate-fire neuron are disposed on the chip.

12. The structure of claim 11 wherein the second magnetic-tunneling-junction layer stack includes a tunnel barrier layer, the tunnel barrier layer of the first magnetic-tunneling-junction layer stack has a first thickness, and the tunnel barrier layer of the second magnetic-tunneling-junction layer stack has a second thickness different from the first thickness.

13. The structure of claim 12 wherein the first thickness ranges from 1 nanometer to 100 nanometers, and the second thickness ranges from 1 nanometer to 100 nanometers.

14. The structure of claim 12 wherein the first magnetic-tunneling-junction layer stack has a first critical dimension, and the second magnetic-tunneling-junction layer stack has a second critical dimension different from the first critical dimension.

15. The structure of claim 11 wherein the second magnetic-tunneling-junction layer stack has a second threshold voltage for generating a second voltage spike, and the second threshold voltage differs from the first threshold voltage.

16. The structure of claim 1 further comprising:
a first wiring level including a first interconnect; and
a second wiring level including a second interconnect,
wherein the first magnetic-tunneling-junction layer stack is disposed between the first wiring level and the second wiring level.

17. The structure of claim 1 wherein the first magnetic-tunneling-junction layer stack includes a free layer, a reference layer, and a tunnel barrier layer between the reference layer and the free layer.

18. The structure of claim 17 wherein the first magnetic-tunneling-junction layer stack includes a synthetic antiferromagnetic pinning layer, and the reference layer is disposed between the tunnel barrier layer and the synthetic antiferromagnetic pinning layer.

19. The structure of claim 1 wherein the power source is a power supply.

20. A method of forming a structure for a spiking neural network, the method comprising:
forming a leaky-integrate-fire neuron including a magnetic-tunneling-junction layer stack,
wherein the magnetic-tunneling-junction layer stack is connected to a power source, and the power source is configured to provide a plurality of voltage pulses to the magnetic-tunneling-junction layer stack.
